(19) United States
(12) Patent Application Publication
(10) Pub. No.: US 2009/0305501 A1
(43) Pub. Date: Dec. 10, 2009

(54) METHOD OF FABRICATING SEMICONDUCTOR DEVICE USING A CHEMICAL MECHANICAL POLISHING PROCESS

(76) Inventors: Tae-hoon Lee, Suwon-si (KR); Il-Young Yoon, Yongin-si (KR); Jae-ouk Choo, Yongin-si (KR)

Correspondence Address: F. CHAU & ASSOCIATES, LLC, 130 WOODBURY ROAD, WOODBURY, NY, 11797, US

(21) Appl. No.: 12/471,035

(22) Filed: May 22, 2009

(30) Foreign Application Priority Data
Jun. 4, 2008 (KR) 10-2008-0052683

(51) Int. Cl. H01L 21/768

(52) U.S. Cl. 438/666; 438/692; 257/E21.585

(57) ABSTRACT

A method of fabricating a semiconductor device by using a chemical-mechanical polishing (CMP) process includes forming an insulating layer on a semiconductor wafer, etching the insulating layer to form via-holes, and forming a conductive layer on the insulating layer to fill the via-holes. The method further includes performing a first polishing process to etch the conductive layer until an upper surface of the insulating layer is exposed,, performing a second polishing process to etch the insulating layer to a predetermined thickness and performing a third polishing process to remove protrusions of the conductive layer.

### CROSS-REFERENCE TO RELATED APPLICATIONS

This application claims the benefit of Korean Patent Application No. 10-2008-0052683, filed on Jun. 4, 2008, the disclosure of which is hereby incorporated by reference herein in its entirety.

### BACKGROUND

(i) Technical Field

The present disclosure relates to a method of fabricating a semiconductor device, and more particularly, to a method of fabricating a semiconductor device by using a chemical-mechanical polishing (CMP) process for removing a tungsten protrusion.

(ii) Description of the Related Art

As the performance and integration degree of semiconductor devices becomes more and more improved, planarization techniques, such as, for example chemical-mechanical polishing (CMP) methods, are being used accordingly. A CMP process may be used, for example, to planarize an inter-level dielectric layer, a metal plug, and a metal interconnection during a multilayer interconnection process. For example, in a CMP process, a surface of a semiconductor wafer on which a metal layer such as a tungsten layer and an insulting layer such as an oxide layer are deposited may be polished by both mechanical friction and a slurry which is a chemical abrasive.

A CMP device performing such a polishing process may include, for example, platens with abrasive pads. For example, to perform CMP using the CMP device, a tungsten layer may be removed to a predetermined thickness by using a hard pad arranged on a first platen, the tungsten layer may be etched using a hard pad arranged on a second platen until an insulating layer is exposed, and then the insulating layer may be etched to a predetermined thickness by using a third platen with a soft pad, thereby obtaining a tungsten plug or a tungsten interconnection,

In a conventional CMP process, as illustrated in FIG. 1, an insulating layer 110 is etched to a predetermined thickness for node separation of tungsten plugs 130. For example, if the insulating layer 110 is etched to the predetermined thickness, portions of the tungsten plugs 130, which protrude compared to an upper surface of the insulating layer 110, are not large. However, in this case, node separation of the tungsten plugs 130 may occur less appropriately at an edge part C of a wafer 100 than at the central part A or the middle part B of the wafer 100 as illustrated in FIG. 2A. If the insulating layer 110 is further etched, for example, to a predetermined thickness Ti, node separation of the tungsten plugs 30 may occur appropriately at the edge part C as at the central part A or the middle part B as illustrated in FIG. 2B. However, in this case, the portions of the tungsten plugs 130, which protrude from the upper surface of the insulating layer 110, may increase.

### SUMMARY

Exemplary embodiments of the present invention may provide a method of fabricating a semiconductor device by using a polishing process of removing a tungsten protrusion.

In accordance with an exemplary embodiment of the present invention, a method of fabricating a semiconductor device by using a chemical-mechanical polishing (CMP) process is provided. The method includes forming an insulating layer on a semiconductor wafer, etching the insulating layer to form via-holes, forming a conductive layer on the insulating layer to fill the via-holes, and performing a first polishing process to etch the conductive layer until an upper surface of the insulating layer is exposed. The method further includes performing a second polishing process to etch the insulating layer to a predetermined thickness and performing a third polishing process to remove protrusions of the conductive layer.

The insulating layer may include an oxide layer. The conductive layer may include a tungsten layer. The first polishing process may be performed to etch the conductive layer with a first slurry, and the first slurry allows the conductive layer to have high etching selectivity with respect to the insulating layer. The second polishing process may be performed to remove the insulating layer with a second slurry, and the second slurry allows the insulating layer to have high etching selectivity with respect to the conductive layer.

The third polishing process may be performed to remove only the protrusions of the conductive layer with a third slurry, with the protrusions protruding from the upper surface of the insulating layer, when the insulating layer is etched. The third slurry may include a slurry that is the same as the first slurry that allows the conductive layer to have high etching selectivity with respect to the insulating layer.

The third polishing process may be performed to remove both the protrusions of the conductive layer which protrude from the upper surface of the insulating layer and the insulating layer to a predetermined thickness, when the insulating layer is etched. The third polishing process may be performed using a third slurry which allows the conductive layer to have no etching selectivity with respect to the insulating layer.

In accordance with another exemplary embodiment of the present invention, a method of fabricating a semiconductor device by using a chemical-mechanical polishing (CMP) device with three platens is provided. The method includes forming an insulating layer on a semiconductor wafer, etching the insulating layer to form via-holes, forming a conductive layer on the insulating layer to fill the via-holes, performing a first polishing process by using the first platen with a first slurry to remove a portion of the conductive layer until an upper surface of the insulating layer is exposed. The method further includes performing a second polishing process by using the second platen with a second slurry to etch the insulating layer so that portions of the conductive layer protrude from the upper surface of the insulating layer and performing a third polishing process by using the third platen with a third slurry to remove the protruded portions of the conductive layer.

The first polishing process may be performed using a hard polishing pad arranged on the first platen. The second polishing process may be performed using a soft polishing pad on the second platen. The third polishing process may be performed using a hard polishing pad on the third platen.

### BRIEF DESCRIPTION OF THE DRAWING

Exemplary embodiments of the present invention can be understood in more detail from the following detailed description taken in conjunction with the accompanying drawings in which:

FIG. 1 is a cross-sectional view of a conventional semiconductor device in which plugs are formed in via-holes;

FIGS. 2A and 2B are diagrams illustrating node separation of plugs according to extent of etching an insulating layer in a conventional semiconductor device;

FIGS. 3A through 3E are cross-sectional views illustrating a method of fabricating a semiconductor device by using a chemical-mechanical polishing (CMP) process according to an exemplary embodiment of the present invention;

FIGS. 4A through 4E are cross-sectional views illustrating a method of fabricating a semiconductor device by using the CMP process according to an exemplary embodiment of the present invention;

FIG. 5A is a schematic top view of a CMP apparatus used for fabricating a semiconductor device according to an exemplary embodiment of the present invention; and

FIG. 5B is a schematic perspective view of the CMP apparatus of FIG. 5A.

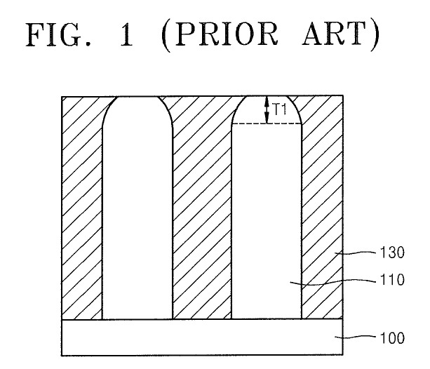

### DETAILED DESCRIPTION OF THE EXEMPLARY EMBODIMENTS

Hereinafter, exemplary embodiments of the present invention will be described more fully with reference to the accompanying drawings. The present invention may, however, be embodied in many different forms and should not be construed as being limited to the exemplary embodiments set forth herein. In the drawings, the shapes of constitutional elements may be exaggerated for clarity. The same reference numerals represent the same elements throughout the drawings.

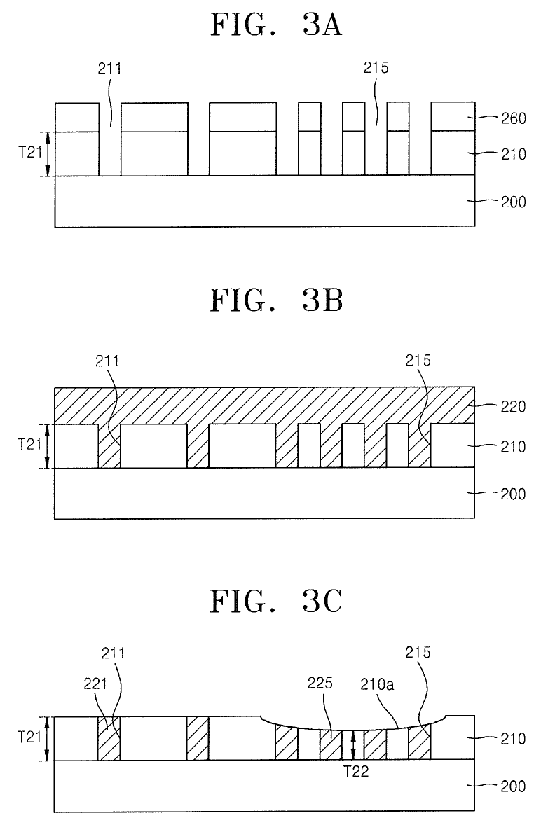

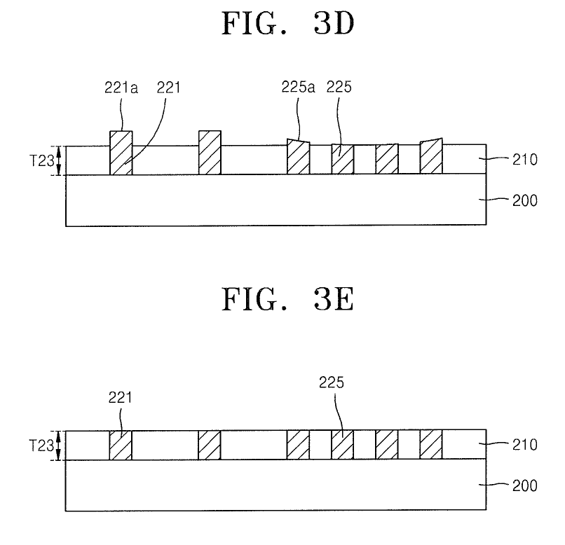

FIGS. 3A through 3C are cross-sectional views illustrating a method of fabricating a semiconductor device by using a chemical-mechanical polishing (CMP) process according to an exemplary embodiment. Referring to FIG. 3A, an insulating layer 210 is formed on a semiconductor wafer 200 to a first thickness T21. The insulating layer 210 may include an inter-level dielectric layer. The insulating layer 210 may include, for example, an oxide layer. A photo sensitive layer 260 is formed on the insulating layer 210 and then patterned to expose portions of the insulating layer 210, in which via-holes are to be formed. With the photo sensitive layer 260 as a mask, the exposed portions of the insulating layer 210 are etched to form via-holes 211 and 215. The second via-holes 215 are arranged to have a higher density than the first via-holes 211.

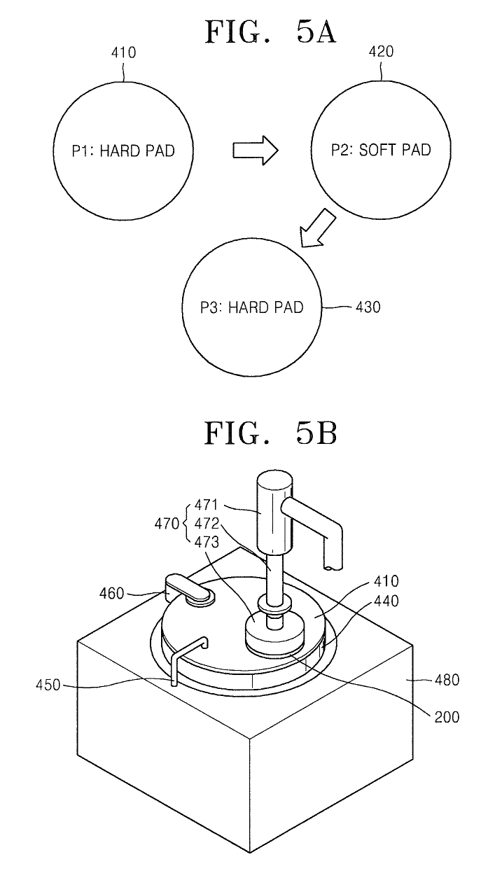

Referring to FIG. 3B, a conductive layer 220 is formed on the insulating layer 210 to be filled with first and second via-holes 211 and 215. For example, the conductive layer 220 may include a tungsten layer. Referring to FIG. 3C, a first CMP process is performed on a surface of the wafer 200 by using a CMP apparatus (FIGS. 5A and 5B). Referring to FIG. 5A, the CMP apparatus may include, for example, three platens 410, 420, and 430. A hard pad P1, a soft pad P2, and a hard pad P3 may be respectively assigned on the first platen 410, the second platen 420 and the third platen 430.

FIG. 5B is a schematic perspective view of the CMP apparatus of FIG. 5A, which shows a first platen 410 of first to third platens 410, 420 and 430 according to an exemplary embodiment. The CMP apparatus includes, for example, the first platen 410, a polishing pad 440, a slurry supply arm 450, a pad conditioner 460 and a polishing head assembly 470. The first platen 410 has, for example, a circular plate structure and is rotated by a rotating body and a motor included in a base 380.

The polishing pad 440 is attached to an upper surface of the platen 410. The polishing pad 440 may have, for example, a hard pad. The slurry supply arm 450 may supply slurry to a surface of the polishing pad 440. The pad conditioner 460 may maintain a polishing condition of the polishing pad 440. The polishing head assembly 470 may absorb the wafer to face a surface of the wafer 200, which is to be polished, toward the polishing pad 440. The polishing head assembly 470 may include, for example, a polishing head 473 that presses the wafer 200 during a CMP process, a driving shaft 472 that rotates the polishing head 473 in a direction in which the first platen 410 rotates, and a motor 471.

For example, the tungsten layer 220 is etched to a predetermined thickness with first slurry using the hard pad P1 that is located on the first platen 410 in FIGS. 5A and 5B. Then the tungsten layer 220 is continuously etched with the first slurry until an upper surface of the insulating layer 210 is exposed, thereby planarizing the surface of the wafer 200. The first slurry may include, for example, a slurry that allows the tungsten layer 220 to have high etching selectivity with respect to the insulating layer 210. Thus first plugs 221 and second plugs 225 are formed in the first and second via-holes 211 and 215.

In this case, the second plugs 225 in the second via-holes 215 having a higher density than the first via-holes 211 may be polished to a greater extent than the first plugs 221 in the first via-holes 211, thereby causing dishing 210a. A portion of the insulating layer 210, which undergoes the dishing 210a, has a second thickness T21 which is less than the first thickness T21 of the insulating layer 210 which is the initial deposition thickness.

Referring to FIG. 3D, a second CMP process is performed on the surface of the wafer 200 by using the CMP device. For example, the insulating layer 210 is etched to a predetermined thickness with a second slurry using the soft polishing pad P2 on the second platen 320, thereby planarizing the surface of the wafer 200. In this case, the insulating layer 210 has a third thickness T23. The second slurry may include, for example, a slurry that allows the insulating layer 220 to have high etching selectivity with respect to the tungsten layer 220. After performing the second CMP process, the insulating layer 210 is etched to remove the dishing 210a. However, protrusions 221a and 225a of the upper surfaces of the first plugs 221 and the second plugs 225, which protrude from the upper surface of the insulating layer 210, may be generated.

Referring to FIG. 3E, a third CMP process is performed on the surface of the wafer 200 by using the CMP device. For example, the first protrusions 221a of the first plugs 221 and the second protrusions 225a of the second plugs 225 are etched with a third slurry using the hard polishing pad P3 on the third platen 330, thereby planarizing the surface of the wafer 200.

In this case, the third slurry may include a slurry that is the same as the first slurry. The third slurry may include a slurry that allows the tungsten layer 220 to have higher etching selectivity with respect to the insulating layer 210. Thus, the insulating layer 210 may be hardly etched and the third thickness T23 of the insulating layer 210 may not substantially change. The tungsten layer 220 is etched to a greater extent than the insulating layer 210, and thus the protrusions 221a and 225a are removed, thereby planarizing the surface of the wafer 200.

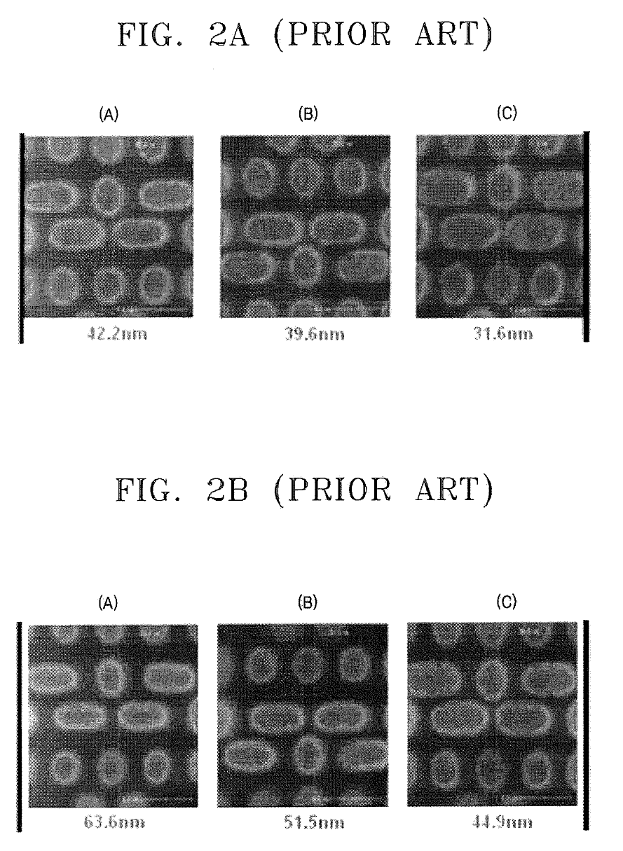

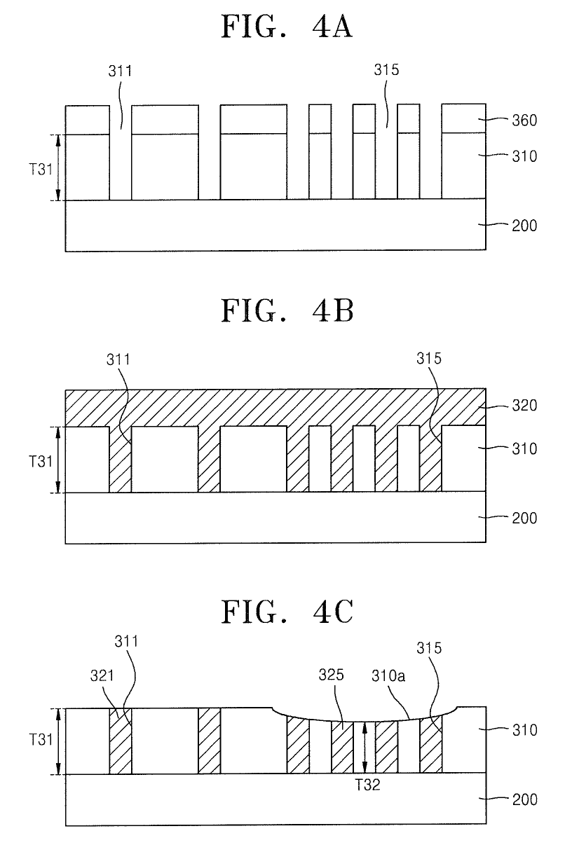

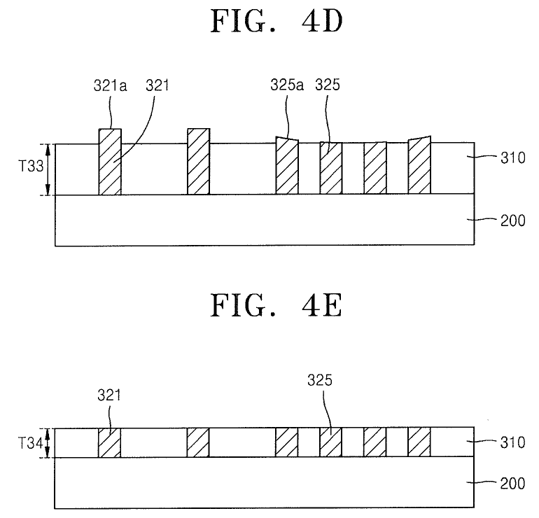

FIGS. 4A through 4E are cross-sectional views illustrating a method of fabricating a semiconductor device by using the CMP process according to another exemplary embodiment. Referring to FIG. 4A, an insulating layer 310 is formed on a semiconductor wafer 200. The insulating layer 310 may include, for example, an oxide layer. The insulating layer 310 may include an inter-level dielectric layer. The insulating layer 310 may have a first thickness T31 which is greater than the first thickness T21 of the insulating layer 210 illustrated in FIG. 2A.

A photo sensitive layer 360 is formed on the insulating layer 310 and then patterned to expose portions of the insulating layer 310, in which via-holes are to be formed. With the photo sensitive layer 360 as a mask, the insulating layer 310 is etched to form via-holes 311 and 315. The second via-holes 315 are arranged to have a higher density than the first via-holes 311.

Referring to FIG. 4B, a conductive layer 320, which is a metal layer such as, for example, a tungsten layer, is formed on the insulating layer 310 to fill the first and second via-holes 311 and 315. Referring to FIG. 4C, a first CMP process is performed on a surface of the wafer 200 by using the CMP device illustrated in FIGS. 5A and 5B. That is, the tungsten layer 320 is etched to a predetermined thickness with a first slurry using the hard polishing pad P1 on the first platen 410 of FIG. 5A. Then, the tungsten layer 320 is continuously etched until an upper surface of the insulating layer 310 is exposed, thereby planarizing the surface of the wafer 200. Accordingly, first plugs 321 and second plugs 325 are respectively formed in the first via-holes 311 and the second via-holes 315.

The first slurry may include, for example, a slurry that allows the tungsten layer 320 to have high etching selectivity with respect to the insulating layer 310. In this case, the second plugs 325 in the second via-holes 315 having a higher density than the first via-holes 311 is polished to a greater extent than the first plugs 321 in the first via-holes 311, thereby causing dishing 310a. The thickness of a portion of the insulating layer 310, where the first plugs 321 with a relatively low density are disposed, is almost equal to the first thickness T31 which is the initial deposition thickness. However, a portion of the insulating layer 310, where the second plugs 325 with a relatively high density are disposed, has a second thickness T32 which is less than the first thickness T31.

Referring to FIG. 4D, a second CMP process is performed on the surface of the wafer 200 by using the CMP device. That is, the insulating layer 310 is etched to a predetermined thickness with a second slurry using the soft polishing pad P2 on the second platen 420, thereby planarizing the surface of the wafer 200. The second slurry may include, for example, a slurry that allows the insulating layer 310 to have high etching selectivity with respect to the tungsten layer 320. After performing the second CMP process, the dishing 210a is removed. However, protrusions 321a and 325a of the upper surfaces of the first plugs 321 and the second plugs 325, which protrude from an upper surface of the insulating layer 310, are generated. In this case, the insulating layer 310 may have a third thickness T33 which is less than the second thickness T32.

Referring to FIG. 4E, a third CMP process is performed on the surface of the wafer 200 by using the CMP device. That is, the first plugs 321, the second plugs 325 and the insulating layer 310 are etched with a third slurry using the hard polishing pad P3 on the third platen 430, thereby planarizing the surface of the wafer 200. In this case, the third slurry may include, for example, a slurry that allows the tungsten layer 320 to have no etching selectivity with respect to the insulating layer 310. Thus, as the third slurry is used to perform the third CMP process, not only the insulating layer 310 but also the first and second plugs 321 and 325 may be etched. Accordingly, the insulating layer 310 may have a fourth thickness T34 which is less than the third thickness T33, and the first and second protrusion 321a and 325a of the first and second plugs 321 and 325 may be removed. The fourth thickness T34 is almost equal to the thickness T33 of FIG. 3E.

Having described the exemplary embodiments of the present invention, it is further noted that it is readily apparent to those of reasonable skill in the art that various modifications may be made without departing from the spirit and scope of the invention which is defined by the metes and bounds of the appended claims.

What is claimed is:

1. A method of fabricating a semiconductor device by using a chemical-mechanical polishing (CMP) process, the method comprising:
forming an insulating layer on a semiconductor wafer;
etching the insulating layer to form via-holes;
forming a conductive layer on the insulating layer to fill the via-holes;
performing a first polishing process to etch the conductive layer until an upper surface of the insulating layer is exposed;
performing a second polishing process to etch the insulating layer to a predetermined thickness; and
performing a third polishing process to remove protrusions of the conductive layer.

2. The method of claim 1, wherein the insulating layer comprises an oxide layer.

3. The method of claim 2, wherein the conductive layer comprises a tungsten layer.

4. The method of claim 2, wherein the first polishing process is performed to etch the conductive layer with a first slurry, and the first slurry allows the conductive layer to have high etching selectivity with respect to the insulating layer.

5. The method of claim 3, wherein the second polishing process is performed to remove the insulating layer with a second slurry, and the second slurry allows the insulating layer to have high etching selectivity with respect to the conductive layer.

6. The method of claim 5, wherein the third polishing process is performed to remove only the protrusions of the conductive layer with a third slurry, the protrusions protruding from the upper surface of the insulating layer, when the insulating layer is etched.

7. The method of claim 6, wherein the third slurry comprises a slurry that is the same as the first slurry that allows the conductive layer to have high etching selectivity with respect to the insulating layer.

8. The method of claim 3, wherein the third polishing process is performed to remove both the protrusions of the conductive layer which protrude from the upper surface of the insulating layer and the insulating layer to a predetermined thickness, when the insulating layer is etched.

9. The method of claim 8, wherein the third polishing process is performed using a third slurry which allows the conductive layer to have no etching selectivity with respect to the insulating layer.

10. A method of fabricating a semiconductor device by using a chemical-mechanical polishing (CMP) device with three platens, the method comprising:
forming an insulating layer on a semiconductor wafer;
etching the insulating layer to form via-holes;
forming a conductive layer on the insulating layer to fill the via-holes;
performing a first polishing process by using the first platen with a first slurry to remove a portion of the conductive layer until an upper surface of the insulating layer is exposed;
performing a second polishing process by using the second platen with a second slurry to etch the insulating layer so that portions of the conductive layer protrude from the upper surface of the insulating layer;
performing a third polishing process by using the third platen with a third slurry to remove the protruded portions of the conductive layer.

11. The method of claim 10, wherein the insulating layer comprises an oxide layer and the conductive layer comprises a tungsten layer.

12. The method of claim 10, wherein the first polishing process is performed using a hard polishing pad on the first platen with the first slurry, and the first slurry allows the conductive layer to have high etching selectivity with respect to the insulating layer.

13. The method of claim 10, wherein the second polishing process is performed by using a soft polishing pad on the second platen with the second slurry, and the second slurry allows the insulating layer to have high etching selectivity with respect to the conductive layer.

14. The method of claim 10, wherein the third polishing process is performed to etch only the protruded portions of the conductive layer protruding from the upper surface of the insulating layer, when the insulating layer is etched.

15. The method of claim 14, wherein the third polishing process is performed using a hard polishing pad on the third platen with the third slurry, the third slurry being the same as the first slurry which allows the conductive layer to have high etching selectivity with respect to the insulating layer.

16. The method of claim 10, wherein the third polishing process is performed to remove both the protrusions of the conductive layer which protrude from the upper surface of the insulating layer and the insulating layer by a predetermined thickness, when the insulating layer is etched.

17. The method of claim 16, wherein the third polishing process is performed using a hard polishing pad on the third platen and the third slurry which allows the conductive layer to have no etching selectivity with respect to the insulating layer.

18. The method of claim 1, wherein the etching of the insulating layer to form via holes includes forming a photo sensitive layer on the insulating layer, patterning the photosensitive layer to expose portions of the insulating layer and etching the exposed portions of the insulating layer to form the via holes using the photosensitive layer as a mask.

19. The method of claim 10, wherein the etching of the insulating layer to form via holes includes forming a photo sensitive layer on the insulating layer, patterning the photosensitive layer to expose portions of the insulating layer and etching the exposed portions of the insulating layer to form the via holes using the photosensitive layer as a mask.

20. The method of claim 19, wherein the via holes include at least a first via hole and a second via hole, wherein the second via hole is arranged to have a higher density than the first via hole.
